(19) United States
(12) Patent Application Publication
(10) Pub. No.: US 2026/0314069 A1
(43) Pub. Date: Oct. 8, 2026

(54) ARRAY SUBSTRATE AND PREPARATION METHOD THEREFOR, AND DISPLAY APPARATUS

(71) Applicants: Nanjing BOE Display Technology CO., LTD., Nanjing,Jiangsu (CN); BOE Technology Group Co., Ltd., Beijing (CN); Beijing BOE Technology Development Co., Ltd., Beijing (CN)

(72) Inventors: Honggang GU, Beijing (CN); Ling YUAN, Beijing (CN)

(21) Appl. No.: 18/880,579

(22) PCT Filed: May 24, 2024
(86) PCT No.: PCT/CN2024/095275

§ 371 Date: Jan. 2, 2025

(30) Foreign Application Priority Data
May 25, 2023 (CN) 202310601565.4

(51) Int. Cl. H10D 86/40; G02F 1/1362; H10D 86/01

(52) U.S. Cl. CPC H10D 86/441; G02F 1/136286; H10D 86/0221

(57) ABSTRACT

An array substrate and a preparation method therefor, and a display apparatus. The array substrate comprises a display area (AA), and a frame area, which is located on at least one side of the display area (AA), wherein the frame area at least comprises a transition area and a circuit area, the circuit area being disposed on the side of the transition area that is away from the display area (AA); the display area (AA) comprises at least one first signal line which extends in a first direction and at least one second signal line which extends in a second direction, the first direction intersects with the second direction, and the transition area comprises at least one dummy signal line (50) which extends in the second direction.

### CROSS-REFERENCE TO RELATED APPLICATION

The present application is a U.S. National Phase Entry of International Application No. PCT/CN2024/095275 having an international filing date of May 24, 2024, which claims priority to Chinese Patent Application No. 202310601565.4 filed to the CNIPA on May 25, 2023 and entitled “Array Substrate and Preparation Method Therefor, and Display Apparatus”. Contents of the above-identified applications are incorporated into the present application by reference.

### TECHNICAL FIELD

The present disclosure relates to, but is not limited to, the field of display technologies, and particularly to an array substrate and a manufacturing method therefor, and a display apparatus.

### BACKGROUND

A Liquid Crystal Display (LCD) has characteristics, such as small volume, low power consumption, and no radiation, and has been developed rapidly. A liquid crystal display panel includes a Thin Film Transistor (TFT) array substrate and a Color Filter (CF) substrate that are in a form of cell. Liquid Crystal (LC) molecules are provided between the array substrate and the color filter substrate. By controlling a common electrode and a pixel electrode, an electric field for driving the liquid crystal to deflect is formed, thereby implementing gray scale display.

### SUMMARY

The following is a summary of subject matters described herein in detail. This summary is not intended to limit the protection scope of claims.

In one aspect, an embodiment of the present disclosure provides an array substrate. The array substrate includes a display area and a bezel area located on at least one side of the display area, the bezel area includes at least a transition region and a circuit region, and the circuit region is disposed on a side of the transition region away from the display area. The display area includes at least one first signal line extending along a first direction and at least one second signal line extending along a second direction, the first direction intersects with the second direction, and the transition region includes at least one dummy signal line extending along the second direction. An orthographic projection of at least one first signal line on the array substrate does not overlap with an orthographic projection of at least one dummy signal line on the array substrate.

In an exemplary embodiment, at least one dummy signal line includes at least one first dummy signal line and at least one second dummy signal line, and the second dummy signal line is located on a side of the first dummy signal line close to the display area. An orthographic projection of the first dummy signal line on the array substrate does not overlap with the orthographic projection of the first signal line on the array substrate, and an orthographic projection of the second dummy signal line on the array substrate at least partially overlaps with the orthographic projection of the first signal line on the array substrate.

In an exemplary embodiment, in the first direction, there is a first distance between an end of the first signal line away from the display area and an edge of the first dummy signal line close to the display area, and there is a second distance between the edge of the first dummy signal line close to the display area and an edge of an adjacent second dummy signal line away from the display area, the first distance being less than the second distance.

In an exemplary embodiment, the first distance is less than or equal to half of the second distance.

In an exemplary embodiment, the bezel area at least includes a first bezel area and a second bezel area, the first bezel area is located on a side of the display area along the first direction, the second bezel area is located on the other side of the display area along the first direction, the circuit region of the first bezel area includes a first scan driver, and the circuit region of the second bezel area includes a second scan driver. The at least one first signal line includes at least one first sub-signal line and at least one second sub-signal line, the first sub-signal line is connected to the first scan driver, and the second sub-signal line is connected to the second scan driver. An orthographic projection of at least one first dummy signal line on the array substrate does not overlap with an orthographic projection of at least one first sub-signal line on the array substrate.

In an exemplary embodiment, an orthographic projection of at least one second dummy signal line on the array substrate at least partially overlaps with the orthographic projection of at least one first sub-signal line on the array substrate.

In an exemplary embodiment, the orthographic projection of at least one first dummy signal line on the array substrate at least partially overlaps with an orthographic projection of at least one second sub-signal line on the array substrate.

In an exemplary embodiment, the orthographic projection of at least one second dummy signal line on the array substrate at least partially overlaps with the orthographic projection of at least one second sub-signal line on the array substrate.

In an exemplary embodiment, the first sub-signal line and the second sub-signal line are alternately disposed along the second direction.

In an exemplary embodiment, a plurality of first signal lines intersect with a plurality of second signal lines to define a plurality of sub-pixels, at least one of the sub-pixels at least includes a transistor and a pixel electrode, a gate electrode of the transistor is connected to a first signal line, a first pole of the transistor is connected to a second signal line, and a second pole of the transistor is connected to the pixel electrode.

In another aspect, an embodiment of the present disclosure further provides a display apparatus, including the array substrate in any of the foregoing embodiments.

In another aspect, an embodiment of the present disclosure further provides a manufacturing method for an array substrate. The array substrate includes a display area and a bezel area located on at least one side of the display area, the bezel area at least includes a transition region and a circuit region, and the circuit region is disposed on a side of the transition region away from the display area.

The manufacturing method includes: forming at least one first signal line and at least one second signal line in the display area, and forming at least one dummy signal line in the transition region. Both the at least one second signal line and the at least one dummy signal line extend along a second direction, the at least one first signal line extends along a first direction, and the first direction intersects with the second direction. An orthographic projection of at least one first signal line on the array substrate does not overlap with an orthographic projection of at least one dummy signal line on the array substrate.

Other aspects of the present disclosure may be comprehended after the drawings and the detailed description are read and understood.

### BRIEF DESCRIPTION OF DRAWINGS

FIG. 1 is a schematic view of a cross-sectional structure of a display apparatus.

FIG. 2 is a schematic diagram of a planar structure of an array substrate according to an exemplary embodiment of the present disclosure.

FIG. 3 is an enlarged schematic diagram of a partial planar structure of an array substrate according to an exemplary embodiment of the present disclosure.

FIG. 4 is a schematic diagram of an array substrate after a pattern of a first conductive layer is formed according to an exemplary embodiment of the present disclosure.

FIG. 5 is a schematic diagram of an array substrate after a pattern of a semiconductor layer is formed according to an exemplary embodiment of the present disclosure.

FIG. 6 is a schematic diagram of an array substrate after a pattern of a second conductive layer is formed according to an exemplary embodiment of the present disclosure.

FIG. 7 is a schematic diagram of an array substrate after a pattern of a second insulation layer is formed according to an exemplary embodiment of the present disclosure.

FIG. 8 is a schematic diagram of an array substrate after a pattern of a third conductive layer is formed according to an exemplary embodiment of the present disclosure.

### DETAILED DESCRIPTION

The embodiments of the present disclosure will be described in detail hereinafter with reference to the drawings. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, an implementation of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred device or element must have a particular orientation, or is constructed and operated in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “electric connection” includes a case where constituent elements are connected through an element with a certain electrical effect. The “element with a certain electrical effect” is not particularly limited as long as electrical signals between the connected constituent elements may be sent and received. Examples of the “element with a certain electrical effect” not only include electrodes and wirings, but also include switching elements such as transistors, resistors, inductors, capacitors, other elements with one or more functions, and the like.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within process and measurement error ranges are allowed.

An embodiment of the present disclosure provides an array substrate. The array substrate includes a display area and a bezel area located at least on a side of the display area, the bezel area at least includes a transition region and a circuit region, and the circuit region is disposed on a side of the transition region away from the display area. The display area includes at least one first signal line extending along a first direction and at least one second signal line extending along a second direction, the first direction intersects with the second direction, and the transition region includes at least one dummy signal line extending along the second direction. An orthographic projection of at least one first signal line on the array substrate does not overlap with an orthographic projection of at least one dummy signal line on the array substrate.

In the array substrate according to an embodiment of the present disclosure, the orthographic projection of at least one first signal line on the array substrate is arranged not to overlap with the orthographic projection of at least one dummy signal line on the array substrate, so that the short circuit problem between the first signal line and the dummy signal line caused by electrostatic discharge can be avoided, the display performance of the display apparatus can be improved, and the qualification rate of the display apparatus can be improved.

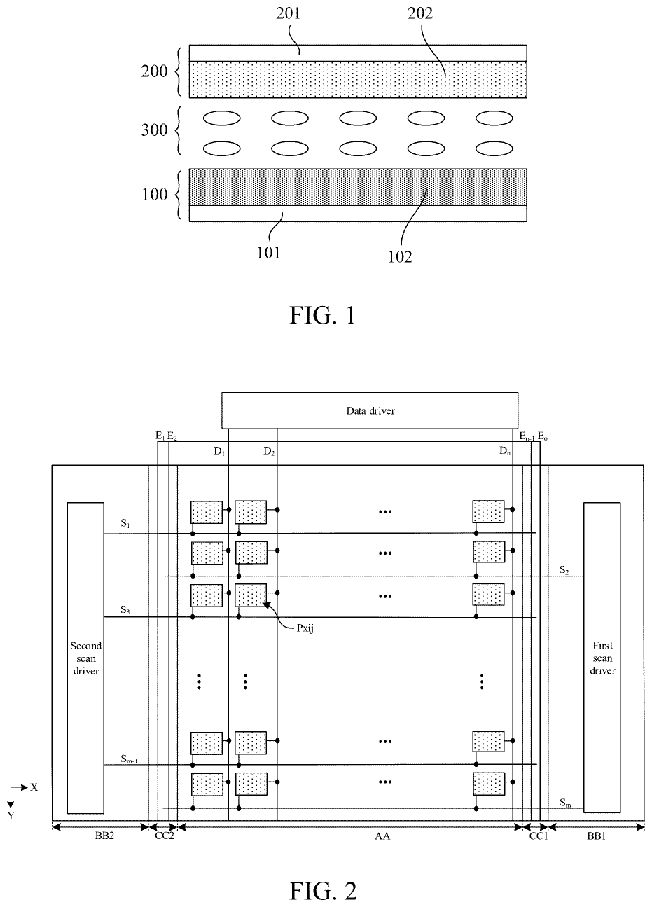

FIG. 1 is a schematic view of a cross-sectional structure of a display apparatus. As shown in FIG. 1, the display apparatus may include a first substrate 100 and a second substrate 200 provided opposite to each other, and a liquid crystal layer 300 provided between the first substrate 100 and the second substrate 200. The first substrate 100 may include a first structural layer 102 provided on a side of a first base substrate 101 facing the second substrate 200, and the second substrate 200 may include a second structural layer 202 provided on a side of a second base substrate 201 facing the first substrate 100. LCD can be categorized into Twisted Nematic (TN) display mode, In Plane Switching (IPS) display mode, Fringe Field Switching (FFS) display mode and Advanced Super Dimension Switch (ADS) display mode or the like in accordance with display mode. For the ADS display mode, in an exemplary implementation, the first structural layer 102 may include a gate line, a data line, a transistor, a pixel electrode, and a common electrode, and the second structural layer 202 may include a black matrix and a filter unit. The transistor may be a Thin Film Transistor (TFT).

FIG. 2 is a schematic diagram of a planar structure of an array substrate according to an exemplary embodiment of the present disclosure. As shown in FIG. 2, in an exemplary implementation, the array substrate may include a display area AA and a bezel area, and the bezel area may be provided on at least one side of the display area AA. For example, the bezel area may be disposed around the display area AA. The bezel area may include a transition region and a circuit region, and the circuit region may be disposed on a side of the transition region away from the display area AA. The bezel area may include a first bezel area and a second bezel area, the first bezel area may be located on a side of the display area AA along the first direction X, and the second bezel area may be located on a side of the display area AA along an opposite direction of the first direction X.

The transition region may include a first transition region CC1 and a second transition region CC2. The circuit region may include a first circuit region BB1 and a second circuit region BB2. For example, the first transition region CC1 and the first circuit region BB1 may be located on a side of the display area AA along the first direction X, that is, the first bezel area may include the first transition region CC1 and the first circuit region BB1. The second transition region CC2 and the second circuit region BB2 may be located on a side of the display area AA along the opposite direction of the first direction X, that is, the second bezel area may include the second transition region CC2 and the second circuit region BB2. The display area AA may include at least one first signal line extending along the first direction X and at least one second signal line extending along the second direction Y. In an embodiment of the present disclosure, the first signal line may be a gate line, and the second signal line may be a data line.

As shown in FIG. 2, the display area AA may include a plurality of gate lines (S₁ to Sₘ) and a plurality of data lines (D₁ to Dₙ). The plurality of gate lines may extend along the first direction X and be sequentially arranged along the second direction Y, the plurality of data lines may extend along the second direction Y and be sequentially arranged along the first direction X, and the plurality of gate lines and the plurality of data lines intersecting with each other define a plurality of sub-pixels Pxij arranged regularly, wherein i and j may be natural numbers. In an exemplary implementation, at least one sub-pixel Pxij may include a transistor, a pixel electrode, and a common electrode, and the transistor is connected with a gate line, a data line, and a pixel electrode, respectively.

In some exemplary implementations, the transition region may include at least one dummy signal line. The plurality of dummy signal lines (E₁ to Eₒ) may extend along the second direction Y and be sequentially arranged along the first direction X.

In some exemplary embodiments, the plurality of dummy signal lines may be connected to a common electrode terminal of the array substrate, and the common electrode terminal may be provided in the bezel area, which can avoid occupying the area of the display area and may improve the display quality of the display apparatus. The common electrode terminal may be connected to a common electrode in the plurality of sub-pixels Pxij.

As shown in FIG. 2, the plurality of dummy signal lines may be respectively provided on both sides of the plurality of data lines along the first direction X. For example, the transition region may include four dummy signal lines, two dummy signal lines are located on a side of the plurality of data lines along the first direction X, and the other two dummy signal lines are located on a side of the plurality of data lines along the opposite direction of the first direction X. In some possible implementations, the transition region may include one dummy signal line, or two dummy signal lines and the like. However, the present disclosure does not limit the number of dummy signal lines included in the transition region. In an exemplary embodiment of the present disclosure, by providing dummy signal lines, uniformity of components of a plurality of film layers of an array substrate in an etching process can be improved, and display quality of the array substrate can be improved.

In some possible exemplary implementations, the transition region only includes the first transition region CC1, and the circuit region only includes the first circuit region BB1. Alternatively, the transition region only includes the second transition region CC2, and the circuit region only includes the second circuit region BB2.

In some exemplary implementations, the plurality of gate lines are connected to a scan driver and extend toward the display area, and the plurality of data lines are connected to a data driver and extend toward the display area. At least a portion of the scan driver and the data driver may be formed on the array substrate. For example, the scan driver and the data driver may be both integrated on the array substrate, which may improve the integration of the array substrate.

In some exemplary implementations, the scan driver may include a first scan driver and a second scan driver. The first scan driver and the second scan driver may be disposed opposite to each other on both sides of the display area. The first circuit region BB1 and the second circuit region BB2 may be disposed opposite to each other on both sides of the display area AA. The first circuit region BB1 may be located on a side of the display area AA along the first direction X, and the second circuit region BB2 may be located on a side of the display area AA along the opposite direction of the first direction X. For example, the first scan driver may be provided in the first circuit region BB1, and the second scan driver may be provided in the second circuit region BB2. For example, a first end of an odd row of gate lines in the plurality of gate lines is connected to the second scan driver in the second circuit region BB2, and a second end of the odd row of gate lines in the plurality of gate lines extends toward the display area AA. A first end of an even row of gate lines in the plurality of gate lines is connected to the first scan driver in the first circuit region BB1, and a second end of the even row of gate lines in the plurality of gate lines extends toward the display area AA. By providing the first scan driver and the second scan driver, the structural complexity and control difficulty of the scan drivers can be reduced, and the service life of the array substrate can be prolonged compared with the technical solution of providing one scan driver.

In some possible exemplary implementations, the first end of the even row of gate lines in the plurality of gate lines is connected to the second scan driver in the second circuit region, and the second end of the even row of gate lines in the plurality of gate lines extends toward the display area. The first end of the odd row of gate lines in the plurality of gate lines is connected to the first scan driver in the first circuit region, and the second end of the odd row of gate lines in the plurality of gate lines extends toward the display area.

In some possible exemplary implementations, a first end of the plurality of gate lines is connected to the second scan driver in the second circuit region, and a second end of the plurality of gate lines extends toward the display area. Alternatively, the first end of the plurality of gate lines is connected to the first scan driver in the first circuit region, and the second end of the plurality of gate lines extends toward the display area.

In some exemplary implementations, an external control device (such as a timing controller) may provide a gray scale value and a control signal suitable for a specification of the data driver to the data driver, and the data driver may generate a data voltage to be provided to the data lines D₁, D₂, D₃, . . . , and Dₙ using the received gray scale value and control signal. For example, the data driver may sample the gray scale value using a clock signal and apply the data voltage corresponding to the gray scale value to the data lines D₁ to Dₙ by taking a row of pixels as a unit, wherein n may be a natural number. The external control device may provide a clock signal, a scan start signal, and the like suitable for a specification of the scan driver to the scan driver, and the scan driver may generate a scan signal to be provided to the gate lines S₁, S₂, S₃, . . . , and Sₘ using the clock signal, the scan start signal, and the like. For example, the scan driver may sequentially provide scan signals with turning-on-level pulses to the gate lines S₁ to Sₘ, wherein m may be a nature number. For example, the scan driver may be constructed in a form of a shift register, and may generate a scan signal in a manner of sequentially transmitting a scan start signal provided in a form of turning-on-level pulses to a next-stage circuit under control of a clock signal.

In some exemplary implementations, the display apparatus may include multiple pixel units arranged in a matrix manner. At least one of the multiple pixel units may include a first sub-pixel that emits light of a first color, a second sub-pixel that emits light of a second color, and a third sub-pixel that emits light of a third color, and the three sub-pixels may each include a transistor, a pixel electrode, and a common electrode. In an exemplary implementation, the first sub-pixel may be a red sub-pixel that emits red (R) light, the second sub-pixel may be a green sub-pixel that emits green (G) light, and the third sub-pixel may be a blue sub-pixel that emits blue (B) light. A shape of the sub-pixels in a pixel unit may be a rectangle, a rhombus, a pentagon, or a hexagon, etc., and the sub-pixels in the pixel unit may be arranged side by side horizontally, side by side vertically, or arranged in a manner of a Chinese character “ [symbol] ”, which is not limited in the present disclosure. In an exemplary implementation, the pixel unit may include four sub-pixels, which is not limited in the present disclosure.

According to the research of the inventors of the present application, it has been found that problems such as abnormal display in the existing liquid crystal display apparatuses are caused by short circuit between dummy signal lines and gate lines. In the process of manufacturing a transistor on the array substrate, a large amount of static electricity is stored in the area where the ends of gate lines are located, and electrostatic discharge (ESD) is easy to occur between an end of a single gate line of a single side drive panel and an adjacent metal component. Since a dummy signal line and a gate line overlap at the end position of the gate line, the electrostatic discharge easily causes the gate insulation layer to be broken down, resulting in short circuit between the dummy signal line and the gate line, thereby causing display abnormality of the display apparatus.

For the array substrate provided according to an embodiment of the present disclosure, the orthographic projection of the at least one first signal line on the array substrate is arranged not to overlap the orthographic projection of the at least one dummy signal line on the array substrate, so that the short circuit problem between the first signal line and the dummy signal line caused by electrostatic discharge can be avoided, the display performance of the display apparatus can be improved, and the qualification rate of the display apparatus can be improved.

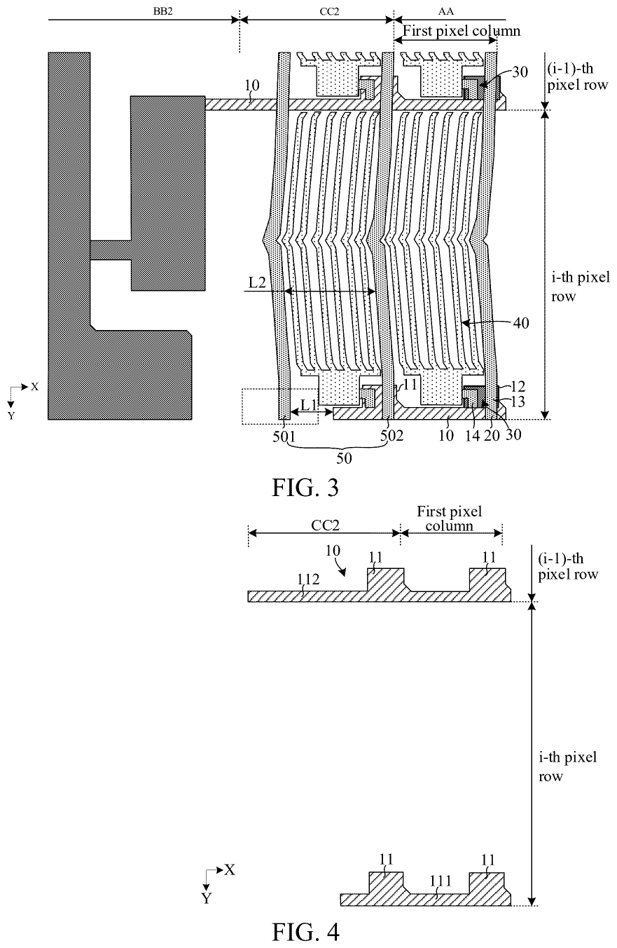

FIG. 3 is an enlarged schematic diagram of a partial planar structure of an array substrate according to an exemplary embodiment of the present disclosure. FIG. 3 is a schematic diagram of a planar structure of an array substrate after a third conductive layer is formed. As shown in FIG. 3, the array substrate may include a plurality of gate lines 10 and a plurality of data lines 20 disposed on a base substrate, the gate line 10 may extend along the first direction X, and the plurality of gate lines 10 may be sequentially disposed along the second direction Y. The data line 20 may extend along the second direction Y, the plurality of data lines 20 may be sequentially arranged along the first direction X, the plurality of gate lines 10 and the plurality of data lines 20 intersecting with each other define a plurality of sub-pixels regularly arranged, and the first direction X intersects with the second direction Y.

In some exemplary implementations, the plurality of sub-pixels may form a plurality of pixel rows and a plurality of pixel columns, one pixel row may include a plurality of sub-pixels disposed at intervals along the first direction X, and the plurality of pixel rows may be disposed at intervals along the second direction Y. One pixel column may include a plurality of sub-pixels disposed at intervals along the second direction Y, and the plurality of pixel columns may be disposed at intervals along the first direction X. FIG. 3 mainly illustrates a sub-pixel located in the i-th row and the first column to indicate the structure of a sub-pixel. In the following description, this sub-pixel refers to the sub-pixel located in the i-th row and the first column, the sub-pixel in the previous row refers to a sub-pixel located in the (i−1)-th row and the first column, and the sub-pixel in the next row refers to a sub-pixel located in the (i+1)-th row and the first column. In FIG. 3, only two dummy signal lines are provided in the second transition region CC2 as an example, and a dummy signal line close to the second circuit region BB2 is denoted as a first dummy signal line 501, a dummy signal line adjacent to the first dummy signal line 501 is denoted as a second dummy signal line 502, and the second dummy signal line 502 is closer to the display area AA than the first dummy signal line 501.

In some exemplary implementations, as shown in FIG. 3, at least one sub-pixel may at least include a transistor 30, a pixel electrode 40, and a common electrode. The transistor 30 may be connected to the gate line 10, the data line 20, and the pixel electrode 40, respectively. For example, the common electrode may be connected to a dummy signal line 50. The transistor 30 is configured to receive a data voltage transmitted by the data line 20 and output the data voltage to the pixel electrode 40 under the control of the gate line 10, and to control the formation of an electric field that drives deflection of the liquid crystal between the pixel electrode 40 and the common electrode to realize gray scale display.

In some possible exemplary implementations, the common electrode may be connected to the dummy signal line via an opening, and an orthographic projection of the opening on the array substrate is located outside an orthographic projection range of the display area on the array substrate, avoiding that the opening occupies the area of the display area, which can improve the display performance of the display apparatus.

In some exemplary implementations, as shown in FIG. 3, the first end of the gate line 10 may be connected to the first scan driver located in the first circuit region, the second end of the gate line 10 may extend along the opposite direction of the first direction X, i.e., extend toward the second circuit region BB2, and an orthographic projection of the second end of the gate line 10 on the array substrate does not overlap with an orthographic projection of the dummy signal line 50 (i.e., the first dummy signal line 501) close to the second circuit region BB2 on the array substrate. In an embodiment of the present disclosure, the orthographic projection of the second end of the gate line on the array substrate is arranged not to overlap with the orthographic projection of the dummy signal line close to the second circuit region on the array substrate, so that short circuit between the dummy signal line and the gate line can be avoided, and the manufacturing yield of the display product can be improved.

In some exemplary implementations, there is a first distance L1 between the orthographic projection of the second end of the gate line 10 on the array substrate and the orthographic projection of the dummy signal line 50 (i.e., the first dummy signal line 501) close to the second circuit region BB2 on the array substrate. There is a second distance L2 between the orthographic projection of the dummy signal line 50 close to the second circuit region BB2 on the array substrate and the orthographic projection of the dummy signal lines 50 adjacent thereto (i.e., the first dummy signal line 501 and the second dummy signal line 502) on the array substrate, the first distance L1 being less than the second distance L2. In an embodiment of the present disclosure, the first distance L1 is a minimum distance between the orthographic projection of the second end of the gate line 10 on the array substrate and the orthographic projection of the dummy signal line 50 (i.e., the first dummy signal line 501) close to the second circuit region BB2 on the array substrate in the first direction X. The second distance L2 is a minimum distance between the orthographic projection of the dummy signal line 50 close to the second circuit region BB2 on the array substrate and the orthographic projection of the dummy signal line 50 adjacent thereto (i.e., the first dummy signal line 501 and the second dummy signal line 502) on the array substrate in the first direction X.

In some exemplary implementations, the first distance may be less than or equal to half of the second distance.

In some exemplary implementations, the plurality of first signal lines may be divided into two parts, a first end of a part of the first signal lines is located in the first circuit region, a second end of the first signal lines extends along the opposite direction of the first direction X toward the second circuit region BB2, and an orthographic projection of the second end on the array substrate does not overlap with an orthographic projection of the dummy signal line in the plurality of dummy signal lines close to the second circuit region BB2 on the array substrate. In an embodiment of the present disclosure, this part of the first signal lines may also be referred to as a first sub-signal line. A first end of the remaining part of the first signal lines is located in the second circuit region BB2, and a second end of the first signal lines extends along the first direction X toward the first circuit region, and the orthographic projection of the second end on the array substrate does not overlap with the orthographic projection of the dummy signal line in the plurality of dummy signal lines close to the first circuit region on the array substrate. In an embodiment of the present disclosure, the remaining part of the first signal lines may also be referred to as a second sub-signal line.

In some exemplary implementations, there is a third distance between an orthographic projection of the second end of the remaining part of the first signal lines on the array substrate and the orthographic projection of the dummy signal line in the plurality of dummy signal lines close to the first circuit region on the array substrate; and there is a fourth distance between orthographic projections of the dummy signal line in the plurality of dummy signal lines close to the first circuit region and the dummy signal line adjacent thereto on the array substrate. The third distance is less than the fourth distance. In an embodiment of the present disclosure, the third distance is a minimum distance between the orthographic projection of the second end of the remaining part of the first signal lines on the array substrate and the orthographic projection of the dummy signal line in the plurality of dummy signal lines close to the first circuit region on the array substrate in the first direction X. The fourth distance is a minimum distance between the orthographic projections of the dummy signal line in the plurality of dummy signal lines close to the first circuit region and the dummy signal line adjacent thereto on the array substrate in the first direction X.

In some exemplary implementations, the third distance may be equal to or less than half of the fourth distance.

In some exemplary implementations, the first distance may be equal to the third distance.

In some exemplary implementations, the second distance may be equal to the fourth distance.

In some exemplary implementations, the transition region may include a plurality of dummy signal lines, and the orthographic projection of at least one first signal line on the array substrate does not overlap with the orthographic projection of the dummy signal line in the plurality of dummy signal lines close to the circuit region on the array substrate, and overlaps with orthographic projections of other dummy signal lines on the array substrate.

In an exemplary embodiment, an orthographic projection of at least one second dummy signal line on the array substrate at least partially overlaps with an orthographic projection of at least one first sub-signal line on the array substrate.

In an exemplary embodiment, an orthographic projection of at least one first dummy signal line on the array substrate at least partially overlaps with the orthographic projection of at least one second sub-signal line on the array substrate.

In an exemplary embodiment, the orthographic projection of at least one second dummy signal line on the array substrate at least partially overlaps with the orthographic projection of at least one second sub-signal line on the array substrate.

In an exemplary embodiment, the first sub-signal line and the second sub-signal line are alternately provided along the second direction.

Exemplary description is made below through a manufacturing process of an array substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B being arranged in a same layer” in the present disclosure means that A and B are formed simultaneously through a same patterning process, and the “thickness” of a film layer is dimension of the film layer in a direction perpendicular to the array substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary implementation, taking the plurality of dummy signal lines including a first dummy signal line and a second dummy signal line, a sub-pixel in the i-th row and the first column, and a lower region of a sub-pixel in the (i−1)-th row and the first column as an example, in an embodiment of the present disclosure, this sub-pixel refers to a sub-pixel in the i-th row and the first column, and this pixel row refers to the i-th pixel row. The manufacturing of the array substrate may include operation steps (1) to (5), and the manufacturing process is schematically illustrated in FIGS. 4 to 8.

(1) Forming a pattern of a first conductive layer. In an exemplary implementation, forming the pattern of the first conductive layer may include: depositing a first conductive thin film on a base substrate, and patterning the first conductive thin film by a patterning process, such that the first conductive thin film forms the pattern of the first conductive layer on the base substrate. The pattern of the first conductive layer at least includes a gate line 10. For example, the pattern of the first conductive layer may include at least one first gate line 111 and at least one second gate line 112. As shown in FIG. 4, only a part of the display area of the array substrate and the second transition region CC2 are schematically illustrated in FIG. 4. In FIG. 4, only one first gate line 111 and one second gate line 112 are schematically illustrated, and in an embodiment of the present disclosure, the first gate line 111 namely is a first sub-signal line, and the second gate line 112 namely is a second sub-signal line.

In an exemplary implementation, the gate line 10 may be in a line shape in which the main body portion extends along the first direction X, and the gate line 10 of each sub-pixel may be disposed on a lower side of the sub-pixel (a side of the sub-pixel close to the sub-pixel in the next row). The gate line 10 is configured to be connected to a transistor in the sub-pixel, providing a gate drive signal to the transistor.

In an exemplary implementation, the gate line 10 may be provided with an equal width, or may be provided with an unequal width, and the width refers to a dimension perpendicular to an extending direction (the second direction Y) of the gate line 10.

In an exemplary implementation, the gate line 10 may be provided with at least one gate protrusion 11. A first end of the gate protrusion 11 may be connected to the gate line 10, and a second end of the gate protrusion 11 may extend along an opposite direction of the second direction Y. An orthographic projection of the gate protrusion 11 on the base substrate may be rectangular. The gate protrusion 11 is located within this sub-pixel. The gate protrusion 11 is located in the same sub-pixel as the gate line 10 connected thereto.

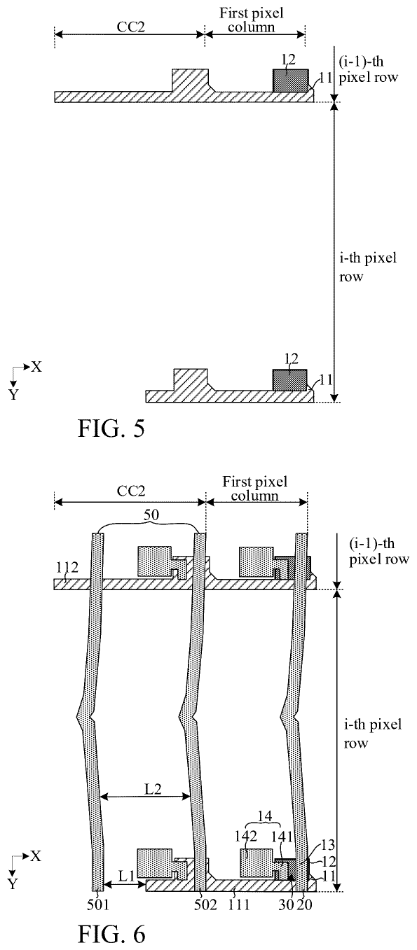

(2) Forming a pattern of a semiconductor layer. In an exemplary implementation, forming the pattern of the semiconductor layer may include: sequentially depositing a first insulation thin film and a semiconductor thin film on the base substrate on which the aforementioned pattern is formed, and patterning the semiconductor thin film by a patterning process, such that the first insulation thin film forms a first insulation layer covering the pattern of the first conductive layer, and such that the semiconductor thin film forms the pattern of the semiconductor layer provided on the first insulation layer, the pattern of the semiconductor layer at least including an active layer provided in each sub-pixel, as shown in FIG. 5, in which only a part of the display area of the array substrate and the second transition region CC2 are schematically illustrated.

In an exemplary implementation, the shape of the active layer 12 within each sub-pixel may be the same, and the structure of the transistor may be simplified. For example, an orthographic projection of the active layer 12 on the base substrate may be square, rectangular, or the like.

In an exemplary implementation, the orthographic projection of the active layer 12 on the base substrate at least partially overlaps with an orthographic projection of the gate protrusion 11 on the base substrate, for example, the orthographic projection of the active layer 12 on the base substrate may be within the range of the orthographic projection of the gate protrusion 11 on the base substrate, and the overlapping region of the gate protrusion 11 and the active layer 12 may serve as a gate electrode of each transistor.

(3) Forming a pattern of a second conductive layer. In an exemplary implementation, forming the pattern of the second conductive layer may include: depositing a second conductive thin film on the base substrate on which the aforementioned pattern is formed, and patterning the second conductive thin film by a patterning process, such that the second conductive thin film forms the pattern of the second conductive layer located on a side of the pattern of the semiconductor layer away from the base substrate. The pattern of the second conductive layer at least may include a source electrode 13 and a drain electrode 14 provided in each sub-pixel, and the pattern of the second conductive layer at least may also include a data line 20 and a dummy signal line 50, as shown in FIG. 6, in which only a part of the display area of the array substrate and the second transition region CC2 are schematically illustrated.

In an exemplary implementation, both the data line 20 and the dummy signal line 50 may be in a broken line shape in which the main body portion extends along the second direction Y. The extending directions of the respective broken lines in the data line 20 and the dummy signal line 50 may be substantially the same.

In an exemplary implementation, the data line 20 and the dummy signal line 50 may be provided in parallel.

In an exemplary implementation, the plurality of dummy signal lines 50 and the plurality of data lines 20 may be provided at equal intervals along the first direction X.

In an exemplary implementation, the data line 20 may be provided on a side (right side) of the sub-pixel along the first direction X. The data line 20 is configured to be connected with the transistor in the sub-pixel, and may provide a data signal to the transistor.

In an exemplary implementation, the data line 20 and the dummy signal line 50 may be provided with an equal width, or may be provided with an unequal width, and this width refers to a dimension perpendicular to an extending direction of the data line 20 and the dummy signal line 50 (namely, the first direction X).

In an exemplary implementation, the dummy signal line 50 may include a first dummy signal line 501 and a second dummy signal line 502, and the first dummy signal line 501 and the second dummy signal line 502 may both be in a broken line shape in which the main body portion extends along the second direction Y. The extending directions of the respective broken lines in the first dummy signal line 501 and the second dummy signal line 502 may be substantially the same. The second dummy signal line 502 may be located on a side of the data line 20 of this sub-pixel along the opposite direction of the first direction X, and the first dummy signal line 501 may be located on a side of the second dummy signal line 502 along the opposite direction of the first direction X. For example, the first end of the gate line 10 of the present pixel row may be connected to the first scan driver located in the first circuit region, and the second end of the gate line 10 of the present pixel row may extend along the opposite direction of the first direction X, that is, the second end of the gate line 10 of the present pixel row extends toward the second circuit region. The orthographic projection of the second end of the gate line 10 of the present pixel row on the array substrate does not overlap with an orthographic projection of the first dummy signal line 501 on the array substrate.

In an exemplary implementation, there is a first distance L1 between the orthographic projection of the second end of the gate line 10 on the array substrate and the orthographic projection of the first dummy signal line 501 on the array substrate. There is a second distance L2 between the orthographic projection of the first dummy signal line 501 on the array substrate and an orthographic projection of the second dummy signal line 502 on the array substrate, for example, the second distance L2 may be equal to twice the first distance L1, or the first distance L1 may be less than half of the second distance L2.

In an exemplary embodiment, the orthographic projection of the second dummy signal line 502 on the array substrate at least partially overlaps with an orthographic projection of the first gate line 111 on the array substrate.

In an exemplary embodiment, the orthographic projection of the first dummy signal line 501 on the array substrate at least partially overlaps with an orthographic projection of the second gate line 112 on the array substrate.

In an exemplary embodiment, the orthographic projection of the second dummy signal line 502 on the array substrate at least partially overlaps the orthographic projection of the second gate line 112 on the array substrate.

In an exemplary embodiment, the first gate line 111 and the second gate line 112 may be alternately provided along the second direction Y.

In an exemplary implementation, the first dummy signal line 501, the second dummy signal line 502, and the plurality of data lines 20 may be arranged at equal intervals along the first direction X.

In an exemplary implementation, an orthographic projection of the source electrode 13 on the base substrate at least partially overlaps with an orthographic projection of the active layer 12 on the base substrate. For example, the orthographic projection of the source electrode 13 on the base substrate may be located within the orthographic projection of the active layer 12 on the base substrate. For example, the source electrode 13 and the data line 20 located in the same sub-pixel may be an integral structure connected to each other. The source electrode may also be referred to as a first pole of the transistor. In an exemplary implementation, there is an overlapping region between the orthographic projection of the data line 20 on the base substrate and the orthographic projection of the active layer 12 on the base substrate, and the overlapping region located in the data line 20 namely is the source electrode of the transistor, so that the rationality of the wirings of the display area can be improved and the size of the display area can be reduced.

In an exemplary implementation, the drain electrode 14 of each sub-pixel may be separately provided. The drain electrode can also be referred to as a second pole of the transistor. An orthographic projection of the drain electrode 14 on the base substrate may at least partially overlap with the orthographic projection of the active layer 12 on the base substrate. The active layer 12 between the source electrode 13 and the drain electrode 14 forms a conductive channel. The transistor 30 may include a gate electrode, an active layer 12, a source electrode 13, and a drain electrode 14.

In an exemplary implementation, the drain electrode 14 may include a first portion 141 and a second portion 142 connected to each other. An orthographic projection of the first portion 141 on the base substrate may be within the range of the orthographic projection of the active layer 12 on the base substrate. A first end of the first portion 141 is close to the gate line 10 and located on a side of the gate line 10 along the opposite direction of the second direction Y, a second end of the first portion 141 extends along the opposite direction of the second direction Y and then extends along the opposite direction of the first direction X, and the shape of the orthographic projection of the first portion 141 on the base substrate may be in an “L” shape. The second portion 142 may be located on a side of the first portion 141 along the opposite direction of the first direction X, and an orthographic projection of the second portion 142 on the base substrate may be rectangular. The second portion 142 may be configured to be connected to a subsequently formed pixel electrode.

In an exemplary implementation, an area of the orthographic projection of the second portion 142 on the base substrate may be larger than an area of the orthographic projection of the first portion 141 on the base substrate, so that the second portion 142 is connected to the subsequently formed pixel electrode, which can improve the reliability of the connection.

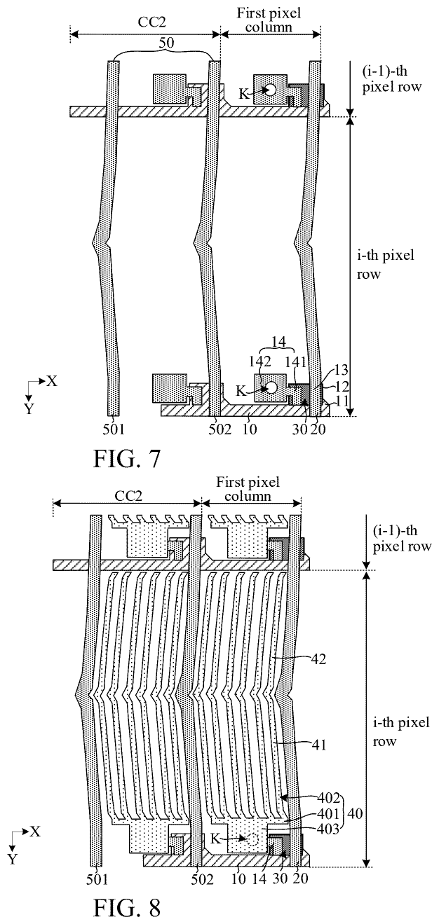

(4) Forming a pattern of a second insulation layer. In an exemplary implementation, forming the pattern of the second insulation layer may include: depositing a second insulation thin film on the base substrate on which the aforementioned pattern is formed, and patterning the second insulation thin film by a patterning process, such that the second insulation thin film forms the pattern of the second insulation layer covering the pattern of the second conductive layer. The pattern of the second insulation layer may include a plurality of vias K, as shown in FIG. 7, in which only a part of the display area of the array substrate and the second transition region CC2 are schematically illustrated.

An orthographic projection of the via K on the base substrate may at least partially overlap with the orthographic projection of the drain electrode 14 on the base substrate, for example, the orthographic projection of the via K on the base substrate may be located within the range of the orthographic projection of the drain electrode 14 on the base substrate. The second insulation layer located within the via K is etched away, and the surface of the drain electrode 14 is exposed, and the via K is configured such that a subsequently formed pixel electrode is connected to the drain electrode 14 through the via.

In an exemplary implementation, the orthographic projection of the via K on the base substrate at least partially overlaps with the orthographic projection of the second portion 142 on the base substrate, for example, the orthographic projection of the via K on the base substrate may be located within the range of the orthographic projection of the second portion 142 on the base substrate. The second insulation layer located within the via K is etched away, and the surface of the second portion 142 is exposed, and the via K is configured such that a subsequently formed pixel electrode is connected to the drain electrode 14 through the via.

In an exemplary implementation, a shape of the via may be any one of the following: square, rectangle, rhombus, circle, ellipse, and the like. The shapes of the plurality of vias may be the same or different.

(5) Forming a pattern of a third conductive layer. In an exemplary implementation, forming the pattern of the third conductive layer may include: depositing a third conductive thin film on the base substrate on which the aforementioned pattern is formed, and patterning the third conductive thin film by a patterning process, so that the third conductive thin film forms the pattern of the third conductive layer located on a side of the pattern of the second insulation layer away from the base substrate. The pattern of the third conductive layer at least may include the pixel electrode 40, as shown in FIG. 8, in which only a part of the display area of the array substrate and the second transition region CC2 are schematically illustrated.

In an exemplary implementation, the pixel electrode 40 in the present sub-pixel may include at least a pixel base portion 401, a pixel pectination portion 402 and a pixel connection portion 403 connected with each other. The pixel base portion 401 may be a strip shape extending along the first direction X and may be located in a lower region of the present sub-pixel (a region close to the next row of sub-pixels). The pixel pectination portion 402 may include a plurality of pixel strip electrodes disposed at intervals along the first direction X, and the plurality of pixel strip electrodes are disposed on a side of the pixel base portion 401 away from the gate line 10, which is also a side of the pixel base portion 401 along the opposite direction of the second direction Y. First ends of the plurality of pixel strip electrodes are connected to the pixel base portion 401, respectively, and second ends of the plurality of pixel strip electrodes extend toward a direction away from the gate line 10, respectively, that is, extend along the opposite direction of the second direction Y, respectively. The pixel connection portion 403 may be in a rectangular shape, and may be provided on a side of the pixel base portion 401 close to the gate line 10, which is also a side of the pixel base portion 401 along the second direction Y. An orthographic projection of the pixel connection portion 403 on the base substrate at least partially overlaps with the orthographic projection of the drain electrode 14 of the transistor 30 on the base substrate. For example, the orthographic projection of the pixel connection portion 403 on the base substrate includes the orthographic projection of the second portion of the drain electrode 14 on the base substrate. The pixel connection portion 403 may be connected to the drain electrode 14 of the transistor 30 through the via K.

In an exemplary implementation, a pixel strip electrode may include a first section 41 and a second section 42 connected to each other. A first end of the first section 41 may be connected to the pixel base portion 401, and a second end of the first section 41 may extend toward a direction away from the gate line 10, that is, extend along the opposite direction of the second direction Y. A first end of the second section 42 may be connected to the second end of the first section 41, a second end of the second section 42 extends toward a direction away from the first section 41, and there may be a spacing along the first direction X between the second end of the first section 41 and the second end of the second section 42. The pixel strip electrodes are designed in sections, so that the array substrate matches the display apparatus with various display modes, improving the display performance.

In an exemplary implementation, the manufacturing process of the array substrate may further include sequentially depositing a third insulation thin film and a fourth conductive thin film on the base substrate on which the aforementioned pattern is formed, and patterning the fourth conductive thin film by a patterning process, such that the third insulation thin film forms a pattern of the third insulation layer covering the pattern of the third conductive layer and such that the fourth conductive thin film forms a pattern of the fourth conductive layer covering the pattern of the third insulation layer. The pattern of the fourth conductive layer at least may include a common electrode.

In an array substrate, a material of a gate line is a metal material, and the gate line occupies a larger area in the array substrate. In the process of manufacturing the transistor on the array substrate, a large amount of static electricity is stored in the area where the gate lines are located, and electrostatic discharge (ESD) is prone to occur between an end of the single gate line of the single side drive panel and an adjacent metal component. The location where electrostatic discharge occurs is shown in the dotted box in FIG. 3. Since the dummy signal line and the gate line overlap at the end position of the gate line, electrostatic discharge easily causes the gate insulation layer to be broken down, resulting in short circuit between the dummy signal line and the gate line, thus causing display abnormality of the display apparatus.

As can be seen from the structure and manufacturing process of the array substrate of the aforementioned embodiments, for the array substrate in an exemplary embodiment of the present disclosure, the length of the gate line is shortened so that the orthographic projections of the second end of the gate line (also the end of the gate line) and the dummy signal line close to the second end of the gate line on the base substrate do not overlap, which can avoid the problem of short circuit between the gate line and the dummy signal line caused by electrostatic discharge at the second end of the gate line, and can improve the reliability of the display apparatus.

For the array substrate according to an exemplary embodiment of the present disclosure, dummy signal lines are provided on both sides of the plurality of data lines, so that the uniformity of the film layer at the edge position of the display area can be improved, and the qualification rate of the display product can be improved.

The manufacturing process of the array substrate according to an exemplary embodiment of the present disclosure may adopt an existing manufacturing process, and the process is simple to implement and is easy to carry out, and has high production efficiency, a low production cost, and a high yield.

In an exemplary implementation, a material of the base substrate may be glass, quartz, or the like. Materials of the first conductive layer and the second conductive layer may be metal materials, such as any one or more of silver (Ag), copper (Cu), aluminum (Al) and molybdenum (Mo), or an alloy material of the above metals, such as an aluminum neodymium alloy (AlNd) or a molybdenum niobium alloy (MoNb), and may be a single-layer structure or a multi-layer composite structure, such as Mo/Cu/Mo, etc. The first conductive layer may be referred to as a gate metal (GATE) layer, and the second conductive layer may be referred to as a source-drain metal (SD) layer. The third conductive layer and the fourth conductive layer may be a single-layer structure, such as indium tin oxide ITO or indium zinc oxide IZO, or may be a multi-layer composite structure, such as ITO/Ag/ITO, etc. Materials of the first insulation layer, the second insulation layer, and the third insulation layer may be any one or more of Silicon Oxide (SiOx), Silicon Nitride (SiNx), and Silicon Oxynitride (SiON), and may be a single layer, a multilayer, or a composite layer. The first insulation layer may be called a gate insulation (GI) layer, and the second insulation layer may be called a passivation (PVX) layer. A material of the active layer may be a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide (Oxide) technology, a silicon technology, or an organic matter technology.

An exemplary embodiment of the present disclosure further provides a display apparatus. The display apparatus may include a first substrate and a second substrate arranged opposite to each other, a liquid crystal layer is disposed between the first substrate and the second substrate, the first substrate may adopt the array substrate according to any of the aforementioned embodiments, and the second substrate may include a black matrix and a filter unit.

In an exemplary implementation, the display apparatus in the present disclosure may be any product or component with a display function, such as a mobile phone, a tablet computer, a television, a display, a notebook computer, a digital photo frame, or a navigator, and an embodiment of the present disclosure is not limited thereto.

An exemplary embodiment of the present disclosure further provides a manufacturing method for the array substrate to manufacture the array substrate provided by any of the aforementioned embodiments. The array substrate includes a display area and a bezel area located at least on a side of the display area, the bezel area at least includes a transition region and a circuit region, and the circuit region is disposed on a side of the transition region away from the display area.

The manufacturing method includes: forming at least one first signal line and at least one second signal line in the display area, and forming at least one dummy signal line in the transition region. Both the at least one second signal line and the at least one dummy signal line extend along a second direction, the at least one first signal line extends along a first direction, and the first direction intersects with the second direction. An orthographic projection of the at least one first signal line on the array substrate do not overlap with an orthographic projection of the at least one dummy signal line on the array substrate.

Although implementations of the present disclosure are described above, contents described are only implementations used for ease of understanding of the present disclosure, but not intended to limit the present disclosure. It should be noted that the above examples or embodiments are exemplary only but not restrictive. Therefore, the present disclosure is not limited to what is specifically shown and described herein. Various modifications, substitutions or omissions may be made in forms and details of implementations without departing from the scope of the present disclosure.

1. An array substrate, comprising: a display area and a bezel area located on at least one side of the display area, wherein the bezel area at least comprises a transition region and a circuit region, and the circuit region is disposed on a side of the transition region away from the display area; the display area comprises at least one first signal line extending along a first direction and at least one second signal line extending along a second direction, the first direction intersects with the second direction, and the transition region comprises at least one dummy signal line extending along the second direction; an orthographic projection of at least one first signal line on the array substrate does not overlap with an orthographic projection of at least one dummy signal line on the array substrate.

2. The array substrate according to claim 1, wherein at least one dummy signal line comprises at least one first dummy signal line and at least one second dummy signal line, the second dummy signal line being located on a side of the first dummy signal line close to the display area; an orthographic projection of the first dummy signal line on the array substrate does not overlap with the orthographic projection of the first signal line on the array substrate, and an orthographic projection of the second dummy signal line on the array substrate at least partially overlaps with the orthographic projection of the first signal line on the array substrate.

3. The array substrate according to claim 2, wherein in the first direction, there is a first distance between an end of the first signal line away from the display area and an edge of the first dummy signal line close to the display area, and there is a second distance between the edge of the first dummy signal line close the display area and an edge of an adjacent second dummy signal line away from the display area, the first distance being less than the second distance.

4. The array substrate according to claim 3, wherein the first distance is less than or equal to half of the second distance.

5. The array substrate according to claim 2, wherein the bezel area at least comprises a first bezel area and a second bezel area, the first bezel area being located on a side of the display area along the first direction, the second bezel area being located on the other side of the display area along the first direction, the circuit region of the first bezel area comprising a first scan driver, and the circuit region of the second bezel area comprising a second scan driver; the at least one first signal line comprises at least one first sub-signal line and at least one second sub-signal line, the first sub-signal line being connected to the first scan driver and the second sub-signal line being connected to the second scan driver; the orthographic projection of at least one first dummy signal line on the array substrate does not overlap with an orthographic projection of at least one first sub-signal line on the array substrate.

6. The array substrate according to claim 5, wherein the orthographic projection of at least one second dummy signal line on the array substrate at least partially overlaps with the orthographic projection of at least one first sub-signal line on the array substrate.

7. The array substrate according to claim 5, wherein the orthographic projection of at least one first dummy signal line on the array substrate at least partially overlaps with an orthographic projection of at least one second sub-signal line on the array substrate.

8. The array substrate according to claim 5, wherein the orthographic projection of at least one second dummy signal line on the array substrate at least partially overlaps with an orthographic projection of at least one second sub-signal line on the array substrate.

9. The array substrate according to claim 5, wherein the first sub-signal line and the second sub-signal line are alternately disposed along the second direction.

10. The array substrate according to claim 1, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

11. A display apparatus, comprising the array substrate according to claim 1.

12. A manufacturing method for an array substrate, wherein the array substrate comprises a display area and a bezel area located on at least one side of the display area, the bezel area at least comprising a transition region and a circuit region, the circuit region being disposed on a side of the transition region away from the display area; the manufacturing method comprises:
forming at least one first signal line and at least one second signal line in the display area, and forming at least one dummy signal line in the transition region, wherein both the at least one second signal line and the at least one dummy signal line extend along a second direction, the at least one first signal line extends along a first direction, and the first direction intersects with the second direction; an orthographic projection of at least one first signal line on the array substrate does not overlap with an orthographic projection of at least one dummy signal line on the array substrate.

13. The array substrate according to claim 2, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

14. The array substrate according to claim 3, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

15. The array substrate according to claim 4, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

16. The array substrate according to claim 5, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

17. The array substrate according to claim 6, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

18. The array substrate according to claim 7, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

19. The array substrate according to claim 8, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.

20. The array substrate according to claim 9, wherein a plurality of first signal lines and a plurality of second signal lines intersect to define a plurality of sub-pixels, and at least one of said sub-pixels at least comprises a transistor and a pixel electrode, a gate electrode of said transistor being connected to a first signal line, a first pole of said transistor being connected to a second signal line, and a second pole of said transistor being connected to said pixel electrode.
